(19) United States
(12) Patent Application Publication
(10) Pub. No.: US 2019/0014679 A1
(43) Pub. Date: Jan. 10, 2019

(54) POWER SUPPLY COPPER BUSBAR AND SERVER

(71) Applicant: INSPUR ELECTRONIC INFORMATION INDUSTRY CO., LTD, Jinan, Shandong (CN)

(72) Inventor: Jimiao CAI, Jinan, Shandong (CN)

(73) Assignee: INSPUR ELECTRONIC INFORMATION INDUSTRY CO., LTD, Jinan, Shandong (CN)

(21) Appl. No.: 15/744,859

(22) PCT Filed: Dec. 13, 2016
(86) PCT No.: PCT/CN2016/109579

§ 371 Date: Jan. 15, 2018

(30) Foreign Application Priority Data
Aug. 31, 2016 (CN) 201610778593.3

(51) Int. Cl. H05K 7/14; H01R 9/18; G06F 1/20

(52) U.S. Cl. CPC H05K 7/1492; H01R 25/16; G06F 1/20; H01R 9/18

(57) ABSTRACT

A power supply copper busbar and a server are provided. The power supply copper busbar includes an upper copper busbar and a lower copper busbar, each of which includes a screwing mechanism, and at least two connecting terminals. The screwing mechanism is configured to connect an external power supply module in a screwing manner. A first connecting terminal of the at least two connecting terminals has a first shape for connecting an external node, and the connection is achieved by providing the external node with a first connecting portion having a shape corresponding to the first shape. A second connecting terminal of the at least two connecting terminals has a second shape for connecting an external fan control unit, and the connection is achieved by providing the external fan control unit with a second connecting portion having a shape corresponding to the second shape.

### FIELD

This application relates to the technical field of electronic circuits, and particularly to a power supply copper busbar and a server.

### BACKGROUND

Cabinet servers generally adopt centralized power supply. In a cabinet server, various components, such as a power supply and nodes, may be connected to a power supply copper busbar. The power supply outputs a voltage to the power supply copper busbar, and the nodes and other components take power from the power supply copper busbar.

At present, the various components are connected to the power supply copper busbar mainly in a plugging manner. For example, a power supply unit (PSU) is plugged onto the power supply copper busbar via a plug, and for another example, a node is connected onto the power supply copper busbar via a plug. The method of connecting the various components in the server onto the power supply copper busbar in a pluggable manner facilitates maintenance in an energized state. However, the connection of this method is not reliable enough, and is apt to cause disconnection due to loosening of the connection. Further, it may cause more wiring and interfaces on the power supply copper busbar and various components, causing the complexity in implementing the device to be increased.

### SUMMARY

A power supply copper busbar and a server are provided according to embodiments of the present application, which can increase the stability of the connection.

A power supply copper busbar is provided according to one aspect of the embodiments of the present application, which includes an upper copper busbar and a lower copper busbar;

each of the upper copper busbar and the lower copper busbar includes a screwing mechanism, and at least two connecting terminals,

the screwing mechanism is connected to an external power supply module in a screwing manner,

a first connecting terminal of the at least two connecting terminals has a first shape for connecting an external node, and the external node is provided with a first connecting portion having a shape corresponding to the first shape, and

a second connecting terminal of the at least two connecting terminals has a second shape for connecting an external fan control unit, and the external fan control unit is provided with a second connecting portion having a shape corresponding to the second shape.

In one possible implementation of the first aspect of the embodiments of the present application, the upper copper busbar is located in the upper power supply area of a cabinet, and the lower copper busbar is located in the lower power supply area of the cabinet, and

a maximum current that can be carried by each of the upper copper busbar and the lower copper busbar is 700 A.

In another possible implementation of the first aspect of the embodiments of the present application, a shield is provided outside both of the upper copper busbar and the lower copper busbar, and the shield is covered with an insulating paint outside,

the shield on both of the upper copper busbar and the lower copper busbar is a closed, non-exposed structure at places where the upper copper busbar and the lower copper busbar are connected to the power supply module by the screwing mechanisms, and

positive and negative connection identification members are provided on the shield of both the upper copper busbar and the lower copper busbar at a part located at the rear of the cabinet.

In yet another possible implementation of the first aspect of the embodiments of the present application, any one of the first shape and the second shape is a tapered structure having a concave portion on each of two sides, and the radius of curvature of the concave portion is 0.3.

A server is further proposed according to a second aspect of the embodiments of the present application, which includes:

a power supply unit, the power supply copper busbar according to any one of aspects described above, at least one set of nodes, at least one fan control unit, and at least one set of fans, specifically,

the power supply unit is connected to the power supply copper busbar in a screwing manner, and is configured to output a power supply voltage to the power supply copper busbar,

each set of nodes include at least two nodes, each of the nodes has a first connecting portion having a shape corresponding to the first shape, and each of the nodes is connected to the power supply copper busbar by the first connecting portion to take power from the power supply copper busbar, and

each fan control unit has a second connecting portion having a shape corresponding to the second shape, and each fan control unit is connected to the power supply copper busbar by the second connecting portion to take power from the power supply copper busbar.

The server further includes a midplane structure, and

the midplane structure is connected to any set of nodes in a pluggable manner to take power from any node of any set of nodes.

Thus, the power supply copper busbar and the server are provided according to the embodiments of the present application, the various components are connected to the power supply copper busbar not in a hot-plugging manner, and the power supply module is connected to the copper busbar in a screwing manner, and the external node and the fan control unit are connected to the copper busbar by the connecting terminals in special shapes. In this way, it ensures the connection between the components and the copper busbar to be more reliable, so it is not easy to cause disconnection due to loosening of the connection, and it avoids more cabling and interfaces on the power supply copper busbar and the various components, thus decreasing the complexity in implementing the device.

### BRIEF DESCRIPTION OF THE DRAWINGS

For more clearly illustrating embodiments of the present application or the technical solutions in the conventional technology, drawings referred to describe the embodiments or the conventional technology will be briefly described hereinafter. The drawings in the following description are examples of the present application, and for the person skilled in the art, other drawings may be obtained based on the drawings without any creative efforts.

FIG. 1 is a schematic view showing the structure of a power supply copper busbar according to an embodiment of the present application.

FIG. 2 is a schematic view showing the structure of a power supply copper busbar according to another embodiment of the present application.

FIG. 3 is a schematic view showing the structure of a first connecting terminal of a power supply copper busbar according to the embodiment of the present application.

FIG. 4 is a schematic view showing the structure of a first connecting terminal of a power supply copper busbar according to another embodiment of the present application.

FIG. 5 is a side view of the power supply copper busbar according to the embodiment of the present application.

FIG. 6 is a schematic view showing the structure of a server according to the embodiment of the present application.

FIG. 7 is a schematic view showing the structure of a server according to another embodiment of the present application.

### DETAILED DESCRIPTION

For making the objects, technical solutions and advantages of the embodiments of the present application more clear, the technical solutions in the embodiments of the present application will be described clearly and completely hereinafter in conjunction with the drawings in the embodiments of the present application. The described embodiments are one part of the embodiments of the present application, rather than all embodiments. Based on the embodiments in the present application, all of other embodiments, made by the person skilled in the art without any creative efforts, fall into the scope of the present application.

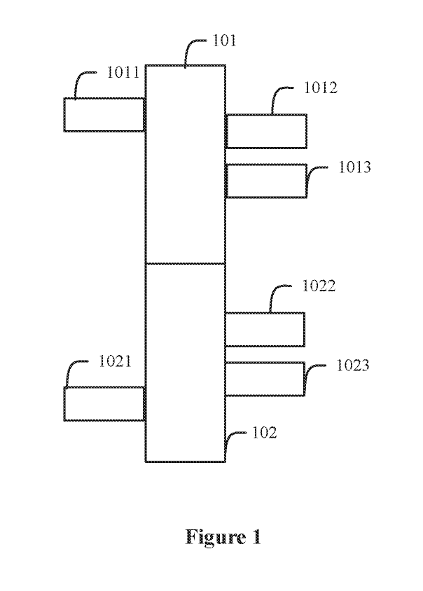

As shown in FIG. 1, a power supply copper busbar is provided according to an embodiment of the present application, which includes an upper copper busbar 101 and a lower copper busbar 102.

The upper copper busbar 101 includes a screwing mechanism 1011, a first connecting terminal 1012, and a second connecting terminal 1013.

The lower copper busbar 102 includes a screwing mechanism 1021, a first connecting terminal 1022, and a second connecting terminal 1023.

The screwing mechanisms 1011 and 1021 are configured to connect an external power supply module in a screwing manner.

The first connecting terminal 1012, 1022 of the at least two connecting terminals has a first shape for connecting an external node, and the connection is achieved by providing the external node with a first connecting portion having a shape corresponding to the first shape.

The second connecting terminal 1013, 1023 of the at least two connecting terminals has a second shape, for connecting an external fan control unit, and the connection is achieved by providing the external fan control unit with a second connecting portion having a shape corresponding to the second shape.

Thus, in the power supply copper busbar according to the embodiment of the present application shown in FIG. 1, various components are connected to the power supply copper busbar not in a hot-plugging manner. Specifically, the power supply module is connected to the copper busbar in a screwing manner, and the external node and the fan control unit are connected to the copper busbar by connecting terminals in special shapes. In this way, it ensures the connection between the components and the copper busbar to be more reliable, and it is not easy to cause disconnection due to loosening of the connection, and more wiring and interfaces on the power supply copper busbar and the various components are avoided, and thus the complexity of the device is decreased.

Also, in the power supply copper busbar according to an embodiment of the present application shown in FIG. 1, for the cabinet server can be divided into two power supply areas, i.e., an upper power supply area and a lower power supply area. The power supply copper busbar also adaptively includes the upper copper busbar and the lower copper busbar. In this way, it is convenient for the components located in the upper power supply area to be connected to the upper copper busbar, and the components located in the lower power supply area to be connected to the lower copper busbar.

In the embodiment of the present application, the upper copper busbar 101 may be located in the upper power supply area of the cabinet, and the lower copper busbar 102 may be located in the lower power supply area of the cabinet, as described above.

Moreover, a maximum current that can be carried each of the copper busbars 101 and 102 is 700 A.

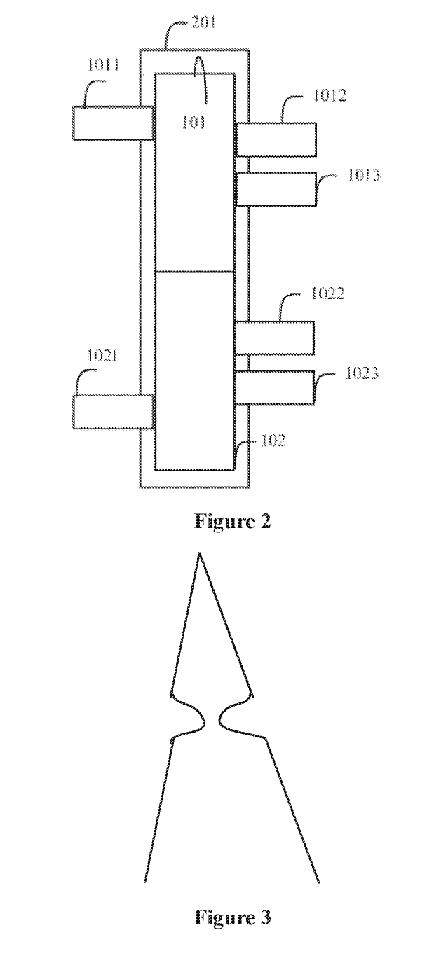

In one embodiment of the present application, referring to FIG. 2, a shield 201 is provided outside both of the upper copper busbar 101 and the lower copper busbar 102, and the shield is covered with an insulating paint (not shown in figures) outside.

Further, the shield 201 on the upper copper busbar 101 and the lower copper busbar 102 is a closed, non-exposed structure at portions where the upper copper busbar 101 and the lower copper busbar 102 are connected to the power supply module by the screwing mechanisms 1011 and 1021.

Further, positive and negative connection identification members are provided on the shield 201 of both of the upper copper busbar 101 and the lower copper busbar 102 at a part located at the rear of the cabinet.

Thus, the power supply copper busbar shown in FIG. 2 has the shield throughout the cabinet for anti-short circuit protection, and the shield is coated with an insulating paint. The shield is also used for protecting the portion where the center of the cabinet is connected to the power supply module, thus the copper busbar at the center of the cabinet is not exposed, avoiding the security risk to operate and maintain the middle portion of the rear of the cabinet, such as a 3 U space.

FIG. 3 is a schematic view showing the structure of the first connecting terminal in one embodiment of the present application. Referring to FIG. 3, in the embodiment of the present application, the first connecting terminal has a first shape that is a tapered structure having a concave portion on each of two sides, and the radius of curvature of the concave portion is 0.3. Of course, in other embodiments, the radius of curvature may also be other values. Based on such a structure, each of the upper copper busbar 101 and the lower copper busbar 102 may be connected to an external node by such a tapered structure having the concave portions on the two sides of FIG. 3. For example, the external node also has a connecting portion, which is a tapered structure having a convex portion on each of two sides, which may realize a close connection with a snapped portion of the first connecting terminal shown in FIG. 3.

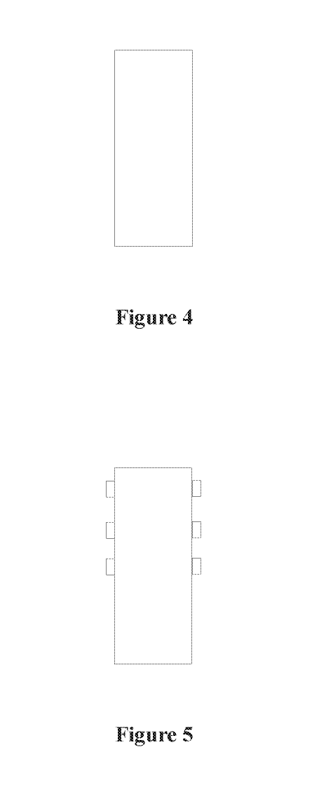

FIG. 4 is a schematic view of another structure of the first connecting terminal according to an embodiment of the present application. Referring to FIG. 4, the first shape of the first connecting terminal may also be rectangular. Based on such a structure, each of the upper copper busbar 101 and the lower copper busbar 102 may be connected to an external node by such a rectangular structure of FIG. 4. For example, the external node also has a connecting portion, which has a structure capable of snapping the rectangular structure, which may realize a close connection with a snapped portion of the first connecting terminal shown in FIG. 4.

It should be noted that the above structures shown in FIGS. 3 and 4 are explained by taking the first shape of the first connecting terminal connected to a node as an example. In the embodiment of the present application, the second shape of the second connecting terminal connected to the fan control unit may employ the same or similar structure as shown in FIG. 3 or 4 to achieve a snap and close connection with the fan control unit in the practical implementation process.

For example, reference is made to FIG. 5, which is a side view of the power supply copper busbar in the case that each of the first connecting terminals 1012 and 1022 and the second connecting terminals 1013 and 1023 is the rectangular structure shown in FIG. 4.

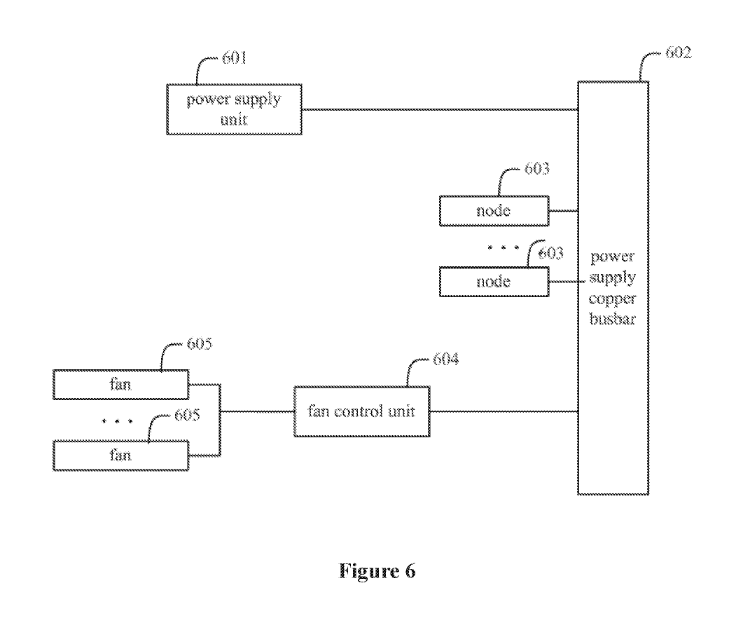

Referring to FIG. 6, a server is further provided according to an embodiment of the present application, which includes:

a power supply unit 601, a power supply copper busbar 602 of the power supply copper busbars provided in any one of the embodiments of the present application, at least one set of nodes 603, at least one fan control unit 604, and at least one set of fans 605.

The power supply unit 601 is connected to the power supply copper busbar 602 in a screwing manner for outputting a power supply voltage to the power supply copper busbar 602;

Each set of nodes include at least two nodes 603, and each of the nodes 603 has a first connecting portion having a shape corresponding to the first shape, and each node is connected to the power supply copper busbar 602 by the first connecting portion to take power from the power supply copper busbar 602.

Each fan control unit 604 has a second connecting portion having a shape corresponding to the second shape, and each fan control unit 604 is connected to the power supply copper busbar 602 by the second connecting portion to take power from the power supply copper busbar 602, and each fan control unit controls a set of fans 605 and outputs the power taken from the power supply copper busbar 602 to each fan 605.

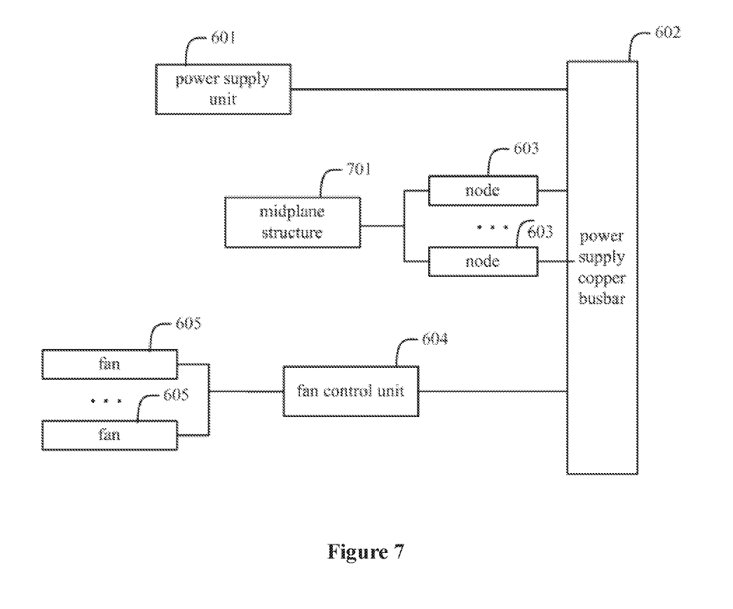

In another embodiment of the present application, in order to further centralize the signals of the nodes for processing, the server may further include a midplane structure 701, as shown in FIG. 7.

The midplane structure 701 is connected to any set of nodes 603 in a pluggable manner to take power from any one node 603 of the any set of nodes.

The various embodiments of the present application have at least the following advantageous effects:

1. In the embodiments of the present application, the various components are connected to the power supply copper busbar not in a hot-plugging manner, and the power supply module is connected to the copper busbar in a screwing manner, and the external node and the fan control unit are connected to the copper busbar by the connecting terminals in special shapes. In this way, it ensures the connection between the components and the copper busbar to be more reliable, so it is not easy to cause disconnection due to loosening of the connection, and it avoids more wiring and interfaces on the power supply copper busbar and the various components, thus decreasing the complexity in implementing the device.

2. In the power supply copper busbar according to the embodiments of the present application, the whole cabinet includes two, upper and lower, power supply areas, i.e., the upper power supply area and the lower power supply area, the power supply copper busbar also adaptively includes the upper copper busbar and the lower copper busbar, in this way, it is convenient for the components located in the upper power supply area to be connected to the upper copper busbar, and the components located in the lower power supply area to be connected to the lower copper busbar.

3. The power supply copper busbar of the embodiments of the present application has the shield throughout the cabinet for anti-short circuit protection, and the shield is coated with an insulating paint; the shield is also used for protecting the connection position between the center of the cabinet and the power supply module, and the copper busbar at the center of the cabinet is not exposed, thus avoiding the security risk in operation and maintenance of the middle portion of the rear of the cabinet, such as 3 U space.

4. In the embodiments of the present application, the connecting terminal on the power supply copper busbar may have a shape that is a tapered structure having the concave portion on each of the two sides, and the radius of curvature of the concave portion is 0.3. Such a structure can realize a more close connection with the node or the fan control unit.

It should be noted that, relational terms such as first and second are merely used to distinguish an entity or an operation from another entity or operation without necessarily requiring or implying that there are any such actual relationships or sequences between these entities or operations herein. Moreover, the term “comprising”, “including”, or any other variant thereof are intended to encompass a non-exclusive inclusion such that processes, methods, articles, or devices that include a series of elements include not only those elements but also those that are not explicitly listed or other elements that are inherent to such processes, methods, articles, or devices. Without limiting more, the elements defined by the statement “comprising one . . . ” do not exclude that there are other identical factors in the process, method, article, or device that includes said elements.

It will be understood by the ordinary person skilled in the art that all or a portion of the steps for implementing the embodiment of the method described above may be accomplished by means of hardware instructed by program instructions. The aforementioned program may be stored in a computer-readable storage medium, and when the program is executed, the steps including the embodiment of the method described above are executed; and the aforementioned storage medium includes a variety of media, such as ROM, RAM, disk, or optical disk, which can store program codes.

Finally, it should be noted that only preferred embodiments of the present application are described above and are merely used to illustrate the technical solution of the present application and are not intended to limit the scope of the present application. Any modifications, equivalent substitutions, improvements, and the like made within the spirit and principle of the present application are intended to be included within the scope of the present application.

1. A power supply copper busbar, comprising:
an upper copper busbar; and
a lower copper busbar;
wherein each of the upper copper busbar and the lower copper busbar comprises a screwing mechanism, and at least two connecting terminals,
the screwing mechanism is connected to an external power supply module in a screwing manner,
a first connecting terminal of the at least two connecting terminals has a first shape for connecting an external node, and the external node is provided with a first connecting portion having a shape corresponding to the first shape, and
a second connecting terminal of the at least two connecting terminals has a second shape for connecting an external fan control unit, and the external fan control unit is provided with a second connecting portion having a shape corresponding to the second shape.

2. The power supply copper busbar according to claim 1, wherein the upper copper busbar is located in the upper power supply area of a cabinet, and the lower copper busbar is located in the lower power supply area of the cabinet, and
a maximum current that is carried by each of the upper copper busbar and the lower copper busbar is 700 A.

3. The power supply copper busbar according to claim 1, wherein a shield is provided outside both of the upper copper busbar and the lower copper busbar, and the shield is covered with an insulating paint outside,
the shield on the upper copper busbar and the lower copper busbar is a closed, non-exposed structure at places where the upper copper busbar and the lower copper busbar are connected to the power supply module by the screwing mechanisms, and
positive and negative connection identification members are provided on the shield of both of the upper copper busbar and the lower copper busbar at a part located at the rear of the cabinet.

4. The power supply copper busbar according to claim 1, wherein any one of the first shape and the second shape is a tapered structure having a concave portion on each of two sides, and the radius of curvature of the concave portion is 0.3.

5. A server, comprising:
a power supply unit;
the power supply copper busbar according to claim 1;
at least one set of nodes;
at least one fan control unit; and
at least one set of fans;
wherein the power supply unit is connected to the power supply copper busbar in a screwing manner, and is configured to output a power supply voltage to the power supply copper busbar,
each set of nodes comprise at least two nodes, each of the nodes has a first connecting portion having a shape corresponding to the first shape, and each of the nodes is connected to the power supply copper busbar by the first connecting portion to take power from the power supply copper busbar, and
each fan control unit has a second connecting portion having a shape corresponding to the second shape, and each fan control unit is connected to the power supply copper busbar by the second connecting portion to take power from the power supply copper busbar.

6. The server according to claim 5, further comprising a midplane structure, wherein
the midplane plate structure is connected to any set of nodes in a pluggable manner to take power from any node of any set of nodes.

7. The power supply copper busbar according to claim 2, wherein any one of the first shape and the second shape is a tapered structure having a concave portion on each of two sides, and the radius of curvature of the concave portion is 0.3.

8. The power supply copper busbar according to claim 3, wherein any one of the first shape and the second shape is a tapered structure having a concave portion on each of two sides, and the radius of curvature of the concave portion is 0.3.

9. A server, comprising:
a power supply unit;
the power supply copper busbar according to claim 2;
at least one set of nodes, at least one fan control unit, and
at least one set of fans;
wherein the power supply unit is connected to the power supply copper busbar in a screwing manner, and is configured to output a power supply voltage to the power supply copper busbar,
each set of nodes comprise at least two nodes, each of the nodes has a first connecting portion having a shape corresponding to the first shape, and each of the nodes is connected to the power supply copper busbar by the first connecting portion to take power from the power supply copper busbar, and
each fan control unit has a second connecting portion having a shape corresponding to the second shape, and each fan control unit is connected to the power supply copper busbar by the second connecting portion to take power from the power supply copper busbar.

10. A server, comprising:
a power supply unit;
the power supply copper busbar according to claim 3;
at least one set of nodes,
at least one fan control unit; and
at least one set of fans;
wherein the power supply unit is connected to the power supply copper busbar in a screwing manner, and is configured to output a power supply voltage to the power supply copper busbar,
each set of nodes comprise at least two nodes, each of the nodes has a first connecting portion having a shape corresponding to the first shape, and each of the nodes is connected to the power supply copper busbar by the first connecting portion to take power from the power supply copper busbar, and
each fan control unit has a second connecting portion having a shape corresponding to the second shape, and each fan control unit is connected to the power supply copper busbar by the second connecting portion to take power from the power supply copper busbar.

11. A server, comprising:
a power supply unit;
the power supply copper busbar according to claim 4;
at least one set of nodes;
at least one fan control unit; and
at least one set of fans;
wherein the power supply unit is connected to the power supply copper busbar in a screwing manner, and is configured to output a power supply voltage to the power supply copper busbar,
each set of nodes comprise at least two nodes, each of the nodes has a first connecting portion having a shape corresponding to the first shape, and each of the nodes is connected to the power supply copper busbar by the first connecting portion to take power from the power supply copper busbar, and
each fan control unit has a second connecting portion having a shape corresponding to the second shape, and each fan control unit is connected to the power supply copper busbar by the second connecting portion to take power from the power supply copper busbar.
